(19) United States
(12) Patent Application Publication
(10) Pub. No.: US 2025/0251048 A1
(43) Pub. Date: Aug. 7, 2025

(54) FLUID SUPPLY SYSTEM, SUBSTRATE PROCESSING APPARATUS, AND FLUID SUPPLY METHOD

(71) Applicant: Tokyo Electron Limited, Tokyo (JP)

(72) Inventors: Takahiro HAYASHIDA, Koshi City (JP); Atsushi TANAKA, Koshi City (JP); Akira KOBAYAKAWA, Koshi City (JP); Fumiya NAKASHIMA, Koshi City (JP); Toshifumi NASU, Koshi City (JP); Shigeru MORIYAMA, Koshi City (JP)

(21) Appl. No.: 19/043,669

(22) Filed: Feb. 3, 2025

(30) Foreign Application Priority Data
Feb. 7, 2024 (JP) 2024-017321

(51) Int. Cl. F16K 11/10; H01L 21/67

(52) U.S. Cl. CPC F16K 11/10; H01L 21/67034

(57) ABSTRACT

A fluid supply system includes: a pipe; a fluid supplier for supplying a fluid to the pipe; opening/closing valves provided in the pipe, each of which having an inflow passage, an outflow passage, and a valve body configured to cause the inflow passage to be in communication with or be blocked from the outflow passage; temperature measurers for measuring a temperature of at least one of a member located downstream of a corresponding opening/closing valve or an inner side of the member; and a leakage determiner for determining whether or not leakage of the fluid occurs in each opening/closing valve. The leakage determiner determines whether or not the leakage of the fluid occurs based on a temperature measured by a corresponding temperature measurer in a state where the inflow passage is filled with a pressurized fluid and an internal pressure of the inflow passage becomes higher than that of the outflow passage.

### CROSS-REFERENCE TO RELATED APPLICATION

This application is based upon and claims the benefit of priority from Japanese Patent Application No. 2024-017321, filed on Feb. 7, 2024, the entire contents of which are incorporated herein by reference.

### TECHNICAL FIELD

The present disclosure relates to a fluid supply system, a substrate processing apparatus, and a fluid supply method.

### BACKGROUND

There is known a substrate processing apparatus that performs a drying process on a substrate using a fluid in a supercritical state (see, for example, Patent Document 1). In such a substrate processing apparatus, a plurality of opening/closing valves is provided in a pipe through which the fluid flows, and the flow of the fluid in the pipe is controlled by appropriately opening or closing the plurality of opening/closing valves.

### PRIOR ART DOCUMENT

### Patent Document

Patent Document 1: Japanese Laid-Open Patent Publication No. 2022-043882

### SUMMARY

According to one embodiment of the present disclosure, a fluid supply system includes: a pipe; a fluid supplier configured to supply a fluid to the pipe so as to cause the fluid to flow from an upstream side to a downstream side in the pipe; a plurality of opening/closing valves provided in the pipe, each of the plurality of opening/closing valves having an inflow passage, an outflow passage, and a valve body configured to cause the inflow passage to be in communication with or be blocked from the outflow passage; a plurality of temperature measurers provided to correspond respectively to the plurality of opening/closing valves, each of the plurality of temperature measurers being configured to measure a temperature of at least one of a member located on a downstream side of a corresponding opening/closing valve among the plurality of opening/closing valves or an inner side of the member; and a leakage determiner configured to determine whether or not leakage of the fluid occurs in the plurality of opening/closing valves, wherein the leakage determiner determines whether or not the leakage of the fluid occurs in each of the plurality of opening/closing valves, based on a temperature measured by a corresponding temperature measurer among the plurality of temperature measurers, in a state in which the inflow passage is filled with a pressurized fluid so that an internal pressure of the inflow passage becomes higher than an internal pressure of the outflow passage as the corresponding opening/closing valve is closed to cause the inflow passage is blocked from the outflow passage by the valve body.

### BRIEF DESCRIPTION OF DRAWINGS

The accompanying drawings, which are incorporated in and constitute a portion of the specification, illustrate embodiments of the present disclosure, and together with the general description given above and the detailed description of the embodiments given below, serve to explain the principles of the present disclosure.

FIG. 1 is a diagram illustrating an example of a configuration of a substrate processing apparatus.

FIG. 2 is a diagram illustrating an example of a configuration of a liquid processing unit.

FIG. 3 is a schematic perspective view illustrating an example of a configuration of a drying unit.

FIG. 4 is a diagram illustrating an example of the configuration of the drying unit.

FIG. 5 is a diagram illustrating an example of a configuration of a supply unit.

FIG. 6 is a diagram illustrating an example of a configuration of a third flow rate regulator and surrounding elements thereof.

FIG. 7 is a diagram illustrating an example of a configuration of a substrate drying process system (including a fluid supply system) including the drying unit (see FIG. 4) and the supply unit (see FIG. 6).

FIG. 8 is a schematic diagram illustrating an example of a configuration of an opening/closing valve (appearance) and a temperature measurer (cross section).

FIG. 9 is a graph (simulation graph) illustrating an example of an internal pressure of an inflow passage of an opening/closing valve and an example of a temperature measured by a corresponding temperature measurer, in which a horizontal axis indicates time (seconds), a vertical axis on the left indicates temperature (degrees C.), and the vertical axis on the right indicates pressure (MPa).

### DETAILED DESCRIPTION

Hereinafter, non-limitative embodiments of the present disclosure will be described. In the following description, directional representations such as “upper”, “lower”, “left” and “right” are merely used for the sake of convenience in description with reference to a state illustrated in a related drawing, unless specified otherwise, and are not intended to limit the actual directionality of each element. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### <Substrate Processing Apparatus>

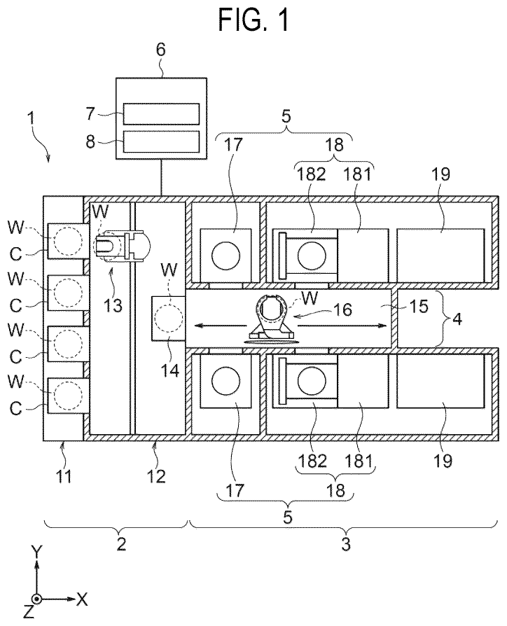

FIG. 1 is a diagram illustrating an example of a configuration of a substrate processing apparatus 1. An X direction, a Y direction, and a Z direction illustrated in FIG. 1 are orthogonal to each other, the X direction and the Y direction coincide with each other in a horizontal direction, and an upward direction along a height direction coincides with a positive Z direction.

The substrate processing apparatus 1 illustrated in FIG. 1 includes a loading/unloading station 2, a processing station 3, and a control device 6. The loading/unloading station 2 and the processing station 3 are provided adjacent to each other.

The loading/unloading station 2 includes a carrier stage 11 and a transferrer 12. A plurality of carriers C (four carriers in FIG. 1), each of which accommodates a plurality of substrates (for example semiconductor wafers) W in a horizontal state, is placed on the carrier stage 11.

The transferrer 12 is provided adjacent to the carrier stage 11. The transferrer 12 is provided with a transfer device 13 and a deliverer 14.

The transfer device 13 includes a substrate holding mechanism that holds the substrate W and transfers the substrate W between the carrier C and the deliverer 14 using the substrate holding mechanism. While holding the substrate W, the substrate holding mechanism of the transfer device 13 is capable of moving the substrate W in the horizontal direction and/or the height direction or rotating the substrate W about a vertical axis.

The processing station 3 is provided adjacent to the transferrer 12 and includes a transfer block 4, a plurality of processing blocks 5, and a plurality of supply units 19.

The transfer block 4 includes a transfer area 15 and a transfer device 16 provided in the transfer area 15. The transfer area 15 is a rectangular parallelepiped area extending in an arrangement direction (the X direction) of the loading/unloading station 2 and the processing station 3. The transfer device 16 includes a substrate holding mechanism that holds the substrate W. The transfer device 16 transfers the substrate W between the deliverer 14 and the plurality of processing blocks 5 using the substrate holding mechanism. While holding the substrate W, the substrate holding mechanism of the transfer device 16 is capable of moving the substrate W in the horizontal direction and/or the height direction or rotating the substrate W around the vertical axis.

The plurality of processing blocks 5 are provided adjacent to the transfer area 15 on both sides of the transfer area 15 (that is, one side and the other side in the Y direction). Although not illustrated in FIG. 1, two or more (for example, three) processing blocks 5 are stacked in the Z direction. The transfer of the substrate W between each of the stacked processing blocks 5 and the deliverer 14 is performed by the transfer device 16.

Although the configuration of each of the processing blocks 5 is not particularly limited, each of the processing blocks 5 illustrated in FIG. 1 includes one liquid processing unit 17 and one drying unit 18 arranged in the X direction along the transfer area 15. The liquid processing unit 17 is closer to the loading/unloading station 2 than the drying unit 18.

In this embodiment, for example, the liquid processing unit 17 performs a cleaning process of cleaning an upper surface of the substrate W, which is a pattern formation surface, and then performs a liquid film formation process of forming a liquid film on the upper surface of the substrate W.

The drying unit 18 performs a supercritical drying process on the substrate W after the liquid film formation process. That is, the drying unit 18 dries the substrate W by bring the substrate W after the liquid film formation process, into contact with a processing fluid in a supercritical state (also referred to as “supercritical fluid”). The drying unit 18 illustrated in FIG. 1 has a processing area 181 and a delivery area 182 arranged in the X direction along the transfer area 15. The delivery area 182 is closer to the liquid processing unit 17 than the processing area 181. In the processing area 181, the supercritical drying process is performed. The delivery area 182 is an area for delivery of the substrate W between the transfer block 4 and the processing area 181.

The supply unit 19 is provided to supply the processing fluid to the drying unit 18. The supply unit 19 may be provided for each processing block 5 or for the plurality of processing blocks 5 (for example, for two or more processing blocks 5 stacked in the Z direction). Alternatively, one common supply unit 19 may be assigned to two or more processing blocks 5.

The supply unit 19 is provided with a supply device group including a flow meter, a flow rate regulator, a backing pressure valve, a heater, and the like, and a housing which accommodates the supply device group. The supply unit 19 of the present embodiment supplies carbon dioxide (CO₂) as the processing fluid to the one or more assigned processing blocks 5.

The control device 6 includes a controller 7 and a storage 8, and may be configured by, for example, a computer. The controller 7 may include a microcomputer equipped with a central processing unit (CPU), a read only memory (ROM), a random access memory (RAM), an input/output port and the like, and various circuits. The CPU of the microcomputer controls various elements (for example, the transfer devices 13 and 16, the liquid processing unit 17, the drying unit 18, the supply unit 19, and the like) of the substrate processing apparatus 1 by reading and executing a program stored in the ROM.

The program may be stored in a non-transitory computer-readable storage medium and installed from the storage medium in the storage 8 of the control device 6. The non-transitory computer-readable storage medium is not particularly limited, and examples thereof may include a hard disk (HD), a flexible disk (FD), a compact disc (CD), a magneto-optical (MO) disk, and a memory card. The storage 8 is implemented by, for example, a semiconductor memory element such as a RAM or a flash memory, or a storage device such as an HD or an optical disc.

In the substrate processing apparatus 1 configured as described above, first, the transfer device 13 of the loading/unloading station 2 takes the substrate W out of the carrier C placed on the carrier stage 11 and places the substrate W on the deliverer 14. The substrate W placed on the deliverer 14 is taken out of the deliverer 14 by the transfer device 16 of the processing station 3 and is loaded into the liquid processing unit 17.

The substrate W loaded into the liquid processing unit 17 is subjected to the cleaning process and the liquid film formation process by the liquid processing unit 17 and then unloaded from the liquid processing unit 17 by the transfer device 16. The substrate W unloaded from the liquid processing unit 17 is loaded into the drying unit 18 by the transfer device 16. The substrate W is subjected to the drying process by the drying unit 18.

The substrate W that has been subjected to the drying process by the drying unit 18 is unloaded from the drying unit 18 by the transfer device 16 and is placed on the deliverer 14. The processed substrate W placed on the deliverer 14 is returned to the carrier C of the carrier stage 11 by the transfer device 13.

### <Liquid Processing Unit>

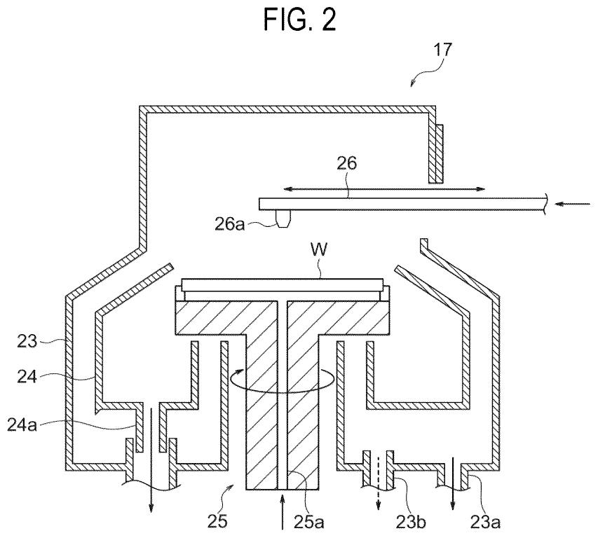

FIG. 2 is a diagram illustrating an example of a configuration of the liquid processing unit 17.

The liquid processing unit 17 illustrated in FIG. 2 is configured as a single-substrate cleaning device that cleans the substrates W one by one by spin cleaning. That is, the liquid processing unit 17 includes a substrate holding mechanism 25. The substrate holding mechanism 25 rotates the substrate W around a vertical axis while holding the substrate W almost horizontally in an inner space (processing space) of an outer chamber 23.

A processing liquid (for example, a chemical liquid and a rinsing liquid) is supplied from above to an upper surface of the rotating substrate W in a predetermined order from a chemical liquid nozzle 26a provided at a tip of a nozzle arm 26, thereby cleaning the upper surface of the substrate W. The nozzle arm 26 illustrated in FIG. 2 is provided to be displaced in the horizontal direction. A radial position of the chemical liquid nozzle 26a relative to the substrate W is changed as the displacement position of the nozzle arm 26 is changed.

The substrate holding mechanism 25 includes a chemical liquid supply path 25a extending in a height direction (the Z direction). One end (upper end) of the chemical liquid supply path 25a faces a lower surface of the substrate W held by the substrate holding mechanism 25. The processing liquid supplied to the chemical liquid supply path 25a is sprayed from the one end of the chemical liquid supply path 25a, adheres to the lower surface of the substrate W and is used to clean the lower surface of the substrate W.

In the cleaning process, for example, first, particles or organic contaminants may be removed by applying SC1 liquid (a mixture of ammonia and hydrogen peroxide), which is an alkaline chemical liquid, to the substrate W. Subsequently, deionized water (hereinafter referred to as “DIW”), which is a rinsing liquid, may be applied to the substrate W to rinse the substrate W.

Subsequently, dilute hydrofluoric acid (hereinafter referred to as “DHF”), which is an acidic chemical liquid, may be supplied to the substrate W to remove a natural oxide film on the substrate W. Thereafter, the rinsing process may be performed on the substrate W by applying DIW to the substrate W.

Various chemical liquids scattered from the substrate W are received by the outer chamber 23 and an inner cup 24 provided in the outer chamber 23. The various chemical liquids received by the outer chamber 23 are discharged from the outer chamber 23 via a drain port 23a provided in a bottom of the outer chamber 23. The various chemical liquids received by the inner cup 24 are discharged from the inner cup 24 via a drain port 24a provided in a bottom of the inner cup 24. An internal atmosphere of the outer chamber 23 is discharged from the outer chamber 23 via an exhaust port 23b provided in the bottom of the outer chamber 23.

The liquid film formation process is performed after the rinsing process in the cleaning process. Specifically, the liquid processing unit 17 supplies isopropyl alcohol (IPA) in a liquid state (hereinafter referred to as “IPA liquid”) to the upper and lower surfaces of the substrate W while the substrate holding mechanism 25 rotates the substrate W. Thus, DIW remaining on both sides of the substrate W is replaced with IPA. Thereafter, the liquid processing unit 17 gently stops the rotation of the substrate W by the substrate holding mechanism 25.

After the liquid film formation process, the substrate W with a liquid film of the IPA liquid formed on the upper surface thereof (that is, with the surface wet by the IPA liquid) is delivered to the transfer device 16 by a delivery mechanism (not illustrated) provided in the substrate holding mechanism 25 and is unloaded from the liquid processing unit 17.

The liquid film on the substrate W is effective in suppressing the occurrence of pattern collapse caused by liquid evaporation (vaporization) on the upper surface of the substrate W during the transfer of the substrate W from the liquid processing unit 17 to the drying unit 18 (including during the loading of the substrate W into the drying unit 18).

### <Configuration of Drying Unit>

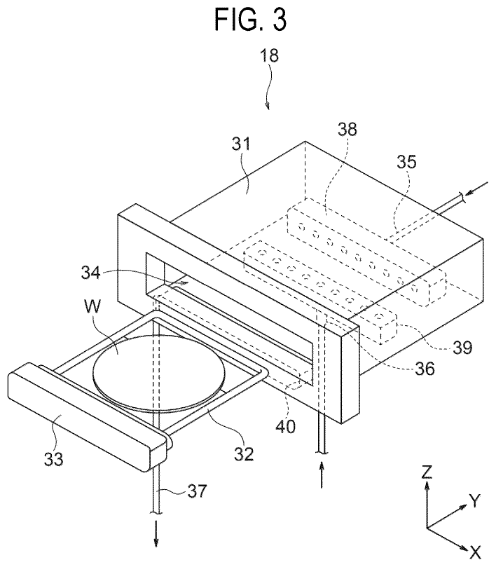

FIG. 3 is a schematic perspective view illustrating an example of a configuration of the drying unit 18.

The drying unit 18 illustrated in FIG. 3 includes a main body 31, a holding plate 32, and a lid member 33. An opening 34 is formed in the main body 31 having a housing shape. The holding plate 32 and the lid member 33 move relative to the main body 31 via the opening 34 to load and unload the substrate W. The holding plate 32 holds the substrate W to be processed in the horizontal direction. The lid member 33 functions as a support member that supports the holding plate 32 and hermitically seals the opening 34 while positioning the substrate W held by the holding plate 32, together with the holding plate 32, in a processing chamber inside the main body 31.

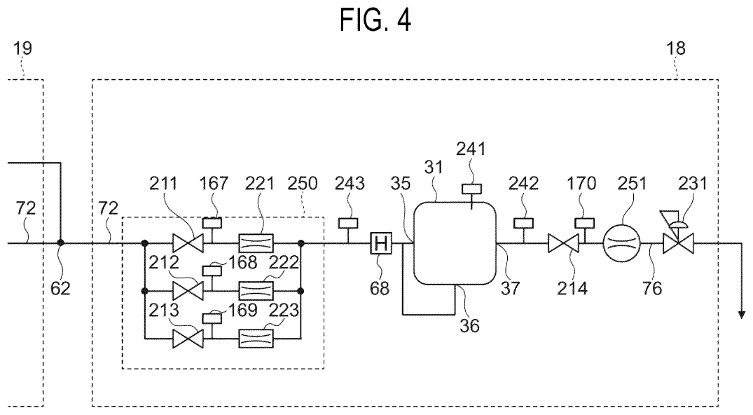

The main body 31 is a container (processing container) in which the processing space (processing chamber) capable of accommodating the substrate W having a diameter of, for example, 300 mm is formed. Supply ports 35 and 36 and a discharge port 37 are provided in walls of the main body 31. A supply flow path (supply pipe) for supplying a supercritical fluid to the drying unit 18 (particularly the processing chamber) is connected to the supply ports 35 and 36. A discharge flow path (discharge pipe) for receiving the supercritical fluid discharged from the drying unit 18 (particularly the processing chamber) is connected to the discharge port 37. In this way, the supply pipe (a second supply line 72 described later (see FIG. 4)) is connected to the processing chamber of the drying unit 18 via the supply ports 35 and 36. The discharge pipe (a discharge line 76 described later (see FIG. 4)) is connected to the processing chamber of the drying unit 18 via the discharge port 37.

The supply port 35 is connected to a side surface of the main body 31 opposite to the opening 34. The supply port 36 is connected to a bottom of the main body 31. The discharge port 37 is connected to a lower side of the opening 34. Although two supply ports 35 and 36 and one discharge port 37 are illustrated in FIG. 3, the number of supply ports and discharge ports is not limited thereto.

Fluid supply headers 38 and 39 and a fluid discharge header 40 are provided inside the main body 31. In each of the fluid supply headers 38 and 39, a plurality of supply ports is formed and arranged in a longitudinal direction of the fluid supply headers 38 and 39. In the fluid discharge header 40, a plurality of discharge ports is formed in a longitudinal direction of the fluid discharge header 40.

The fluid supply header 38 is provided adjacent to the side surface of the main body 31 opposite to the opening 34 inside the main body 31 and is connected to the supply port 35. The plurality of supply ports formed side by side in the fluid supply header 38 faces the opening 34.

The fluid supply header 39 is provided in the center of a bottom of the main body 31 inside the main body 31 and is connected to the supply port 36. The plurality of supply ports formed side by side in the fluid supply header 39 faces upward.

The fluid discharge header 40 is provided adjacent to a side surface of the opening 34 inside the main body 31 and is provided below the opening 34. The fluid discharge header 40 is connected to the discharge port 37. The plurality of discharge ports formed side by side in the fluid discharge header 40 faces upward.

The fluid supply headers 38 and 39 supply the supercritical fluid to the processing chamber inside the main body 31. The fluid discharge header 40 guides the supercritical fluid in the processing chamber inside the main body 31 to the outside of the main body 31 and discharges the supercritical fluid. The supercritical fluid discharged to the outside of the main body 31 via the fluid discharge header 40 contains an IPA liquid dissolved in the supercritical fluid from the front surface of the substrate W.

FIG. 4 is a diagram illustrating an example of the configuration of the drying unit 18.

The second supply line 72 of the supply unit 19 is connected to the drying unit 18 illustrated in FIG. 4. The second supply line 72 branches into two supply lines in the drying unit 18, one supply line being connected to the supply port 35, and the other supply line being connected to the supply port 36. The second supply line 72 of the drying unit 18A is provided with a first flow rate regulator 250, a pressure sensor 243, and a heater 68 in the named order from the upstream side (the supply unit 19).

The first flow rate regulator 250 includes opening/closing valves 211 to 213 and orifices 221 to 223 and regulates a flow rate of the processing fluid to be supplied to the main body 31.

The opening/closing valves 211 to 213 are connected in parallel to each other to the second supply line 72. The opening/closing valves 211 to 213 allow the processing fluid to flow to the orifices 221 to 223 in an open state and do not allow the processing fluid to flow to the orifices 221 to 223 in a closed state by adjusting on and off of the flow of the processing fluid.

The orifices 221 to 223 are connected serially to the opening/closing valves 211 to 213, respectively, and serve to regulate pressure by reducing the flow rate of the processing fluid in a gaseous state or a liquid state supplied from the supply unit 19 via the opening/closing valves 211 to 213. In this way, the orifices 221 to 223 are capable of circulating the processing fluid with the regulated pressure through the second supply line 72 provide on the downstream side.

The pressure sensor 243 measures the pressure of the processing fluid flowing through the second supply line 72 between the first flow rate regulator 250 and the heater 68. That is, the pressure sensor 243 may measure the pressure on a secondary side (downstream side) of the orifices 221 to 223. Output (measurement result) of the pressure sensor 243 is sent to the control device 6.

The heater 68 heats the processing fluid in a gaseous state or a liquid state flowing through the second supply line 72 to generate a supercritical processing fluid. The heater 68 may be configured by, for example, a spiral heater wound around the second supply line 72. However, a specific configuration of the heater 68 is not limited thereto.

The discharge line 76 is connected to the discharge port 37. The discharge line 76 is provided with a pressure sensor 242, an opening/closing valve 214, a flow meter 251, and a backing pressure valve 231 in the named order from the upstream side, that is, the main body 31 side.

The pressure sensor 242 measures the pressure of the processing fluid flowing through a place immediately beyond the main body 31 in the discharge line 76 and transmits its measurement result to the control device 6. In this embodiment, a value of the pressure of the processing fluid measured by the pressure sensor 242 may be substantially regarded as a pressure value of the processing fluid inside the main body 31 (that is, the processing chamber).

The opening/closing valve 214 allows the processing fluid to flow to the discharge line 76 of the downstream side in an open state and does not allow the processing fluid to flow to the discharge line 76 of the downstream side by adjusting on and off of the flow of the processing fluid.

The flow meter 251 measures a flow rate (discharge flow rate) of the processing fluid flowing through the discharge line 76. Output (measurement result) of the flow meter 251 is transmitted to the control device 6.

When the pressure on a primary side (upstream side) of the discharge line 76 exceeds a set pressure, the backing pressure valve 231 regulates an opening degree thereof to allow the fluid to flow to a secondary side (downstream side), thereby maintaining the pressure on the primary side at the set pressure. For example, the set pressure of the backing pressure valve 231 is regulated by the control device 6 based on the output of the pressure sensor 242.

A temperature sensor 241 is provided to detect the temperature of the processing fluid inside the main body 31 (the processing chamber). Output (detection result) of the temperature sensor 241 is transmitted to the control device 6.

In the drying unit 18 (particularly the processing chamber of the main body 31), an IPA liquid between patterns formed on the substrate W gradually dissolves in the supercritical fluid by coming into contact with the supercritical fluid in a high pressure state (for example, 16 MPa) and is gradually replaced with the supercritical fluid. Then, lastly, the patterns are filled with only the supercritical fluid, and the IPA liquid is removed from the patterns.

After the IPA liquid is removed from the patterns, as the internal pressure of the main body 31 (the processing chamber) is reduced from a high pressure state to atmospheric pressure under the control of the control device 6, the processing fluid (CO₂) inside the main body 31 changes from a supercritical state to a gaseous state, and the patterns are occupied by only gas. In this way, the IPA liquid between the patterns is removed so that the drying process on the substrate W is completed.

The supercritical fluid has lower viscosity than a liquid (for example, IPA liquid), has a high capability to dissolve the liquid. Further, an interface is hardly present between the supercritical fluid and a liquid or gas that is in equilibrium with the supercritical fluid. Therefore, according to the drying process using the supercritical fluid, the patterns on the substrate W may be dried while suppressing an influence of surface tension, and thus collapse of the patterns during the drying process may be suppressed.

In the example of the present embodiment, while the IPA liquid has been used as a liquid for drying prevention, and CO₂ in a supercritical state has been used as the processing fluid, a liquid other than IPA liquid may be used as the liquid for drying prevention, and a fluid other than CO₂ in a supercritical state may be used as the processing fluid.

### <Configuration of Supply Unit>

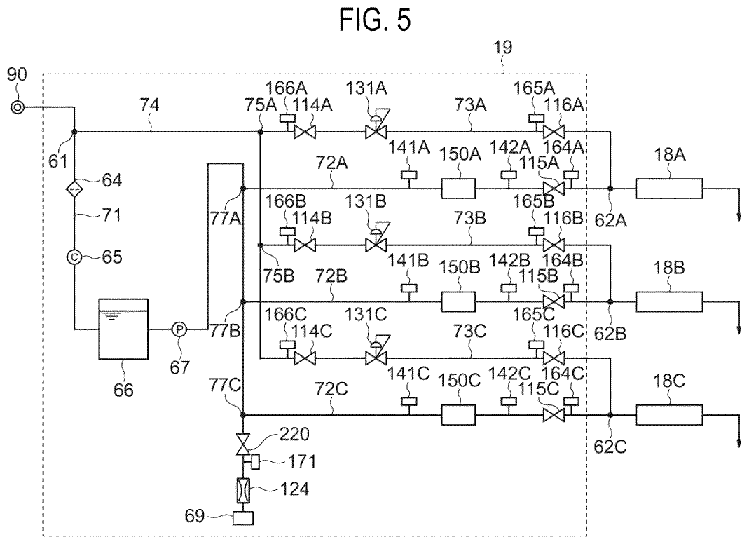

FIG. 5 is a diagram illustrating an example of a configuration of the supply unit 19.

The supply unit 19 illustrated in FIG. 5 supplies the processing fluid to three drying units 18A, 18B, and 18C. Each of the drying units 18A to 18C illustrated in FIG. 5 corresponds to the drying unit 18 illustrated in FIG. 4.

The supply unit 19 includes a first supply line 71 connected to a processing fluid source (fluid supplier) 90, and multiple (three) second supply lines 72A, 72B, and 72C connected to the first supply line 71. Each of the second supply lines 72A to 72C illustrated in FIG. 5 corresponds to the second supply line 72 illustrated in FIG. 4, and each of branch points 62A to 62C illustrated in FIG. 5 corresponds to the branch point 62 illustrated in FIG. 4.

The processing fluid source 90 supplies the processing fluid to the pipe so that the processing fluid flows from the upstream side to the downstream side in the pipe (the first supply line 71, the second supply lines 72A to 72C, and the like).

The second supply lines 72A to 72C are connected to the first supply line 71 at a plurality of branch points 77A, 77B, and 77C provided on the first supply line 71. Specifically, the second supply line 72A is connected to the first supply line 71 at the branch point 77A, and the second supply line 72B and the second supply line 72C are connected to the first supply line 71 at the branch points 77B and 77C, respectively. The second supply line 72A is connected to the drying unit 18A, the second supply line 72B is connected to the drying unit 18B, and the second supply line 72C is connected to the drying unit 18C.

In the first supply line 71, an opening/closing valve 220, a temperature measurer 171, an orifice 124, and an exhauster 69 are sequentially provided on further downstream side of the branch points 77A to 77C. An outlet of the opening/closing valve 220 is connected to the exhauster 69 via the first supply line 71. In the first supply line 71, the temperature measurer 171, and the orifice 124 that locally narrows a flow path through which the processing fluid flows are provided between the opening/closing valve 220 and the exhauster 69. The exhauster 69 may be configured as, for example, an exhaust duct, and exhausts gas sent from the upstream side in the first supply line 71 via the orifice 124 from the first supply line 71.

While the temperature measurer 171 is provided between the opening/closing valve 220 and the orifice 124 (that is, on the upstream side of the orifice 124) in the example illustrated in FIG. 5, the temperature measurer 171 may be provided on the downstream side of the orifice 124. For example, the temperature measurer 171 may be configured to measure the temperature of the exhauster 69 (for example, a surface of the exhaust duct).

The first supply line 71 is provided with a connection point 61, a filter 64, a capacitor 65, a tank 66, and a pump 67 in the named order from the upstream side (the processing fluid source 90 side).

The filter 64 filters the processing fluid in a gaseous state flowing through the first supply line 71 to remove foreign substances contained in the processing fluid. By removing the foreign substances from the processing fluid using the filter 64, it is possible to suppress particles from occurring on the surface of the substrate W during the drying process on the substrate W using the supercritical fluid.

The capacitor (cooler) 65 is connected to, for example, a cooling water supplier (not illustrated) and exchanges heat between cooling water from the cooling water supplier and the processing fluid in a gaseous state flowing through the first supply line 71. Thus, the capacitor 65 cools the process fluid in a gaseous state flowing through the first supply line 71 to produce the processing fluid in a liquid state.

The tank 66 stores the processing fluid in the liquid state produced by the capacitor 65. The pump 67 sends the processing fluid in the liquid state stored in the tank 66 to the downstream side of the first supply line 71.

The branch point 62A is provided on the second supply line 72A, the branch point 62B is provided on the second supply line 72B, and the branch point 62C is provided on the second supply line 72C. The branch point 62A is provided between an opening/closing valve 115A and the drying unit 18A, the branch point 62B is provided between an opening/closing valve 115B and the drying unit 18B, and the branch point 62C is provided between an opening/closing valve 115C and the drying unit 18C. The supply unit 19 includes a first branch line 73A connected to the branch point 62A, a first branch line 73B connected to the branch point 62B, and a first branch line 73C connected to the branch point 62C.

The first branch line 73A is provided with an opening/closing valve 116A, a backing pressure valve 131A, and an opening/closing valve 114A in the named order from the upstream side (the branch point 62A side). The first branch line 73B is provided with an opening/closing valve 116B, a backing pressure valve 131B, and an opening/closing valve 114B in the named order from the upstream side (the branch point 62B side). The first branch line 73C is provided with an opening/closing valve 116C, a backing pressure valve 131C, and an opening/closing valve 114C in the named order from the upstream side (the branch point 62C side).

The opening/closing valve 116A allows the processing fluid to flow to the first branch line 73A of the downstream side in an open state and does not allow the processing fluid to flow to the first branch line 73A of the downstream side in a closed state by adjusting on and off of the flow of the processing fluid. The opening/closing valves 116B and 116C have the same configuration as the opening/closing valve 116A.

When a pressure of a primary side of the first branch line 73A exceeds a set pressure, the backing pressure valve 131A adjusts an opening degree thereof to allow the fluid to flow to a secondary side, thereby maintaining the pressure of the primary side at the set pressure. For example, the set pressure of the backing pressure valve 131A is regulated by the control device 6 based on outputs of a pressure sensor 142A and the pressure sensor 243. The backing pressure valves 131B and 131C have the same configuration as the backing pressure valve 131A.

The opening/closing valve 114A allows the processing fluid to flow to the first branch line 73A of the downstream side in an open state and does not allow the processing fluid to flow to the first branch line 73A of the downstream in a closed state by adjusting on and off of the flow of the processing fluid. The opening/closing valves 114B and 114C have the same configuration as the opening/closing valve 114A.

The supply unit 19 includes a second branch line 74 connected to the first branch lines 73A to 73C. The first branch lines 73A to 73C are connected to the second branch line 74 at a plurality of connection points 75A and 75B provided on the second branch line 74. Specifically, the first branch line 73A is connected to the second branch line 74 at the connection point 75A, and the first branch line 73B and the first branch line 73C are connected to the second branch line 74 at the connection point 75B. The second branch line 74 is connected to the connection point 61. That is, the second branch line 74 connects the first branch lines 73A to 73C and the connection point 61. Alternatively, the second branch line 74 may be omitted, and the first branch lines 73A to 73C may be directly connected to the first supply line 71 on the upstream side of the filter 64 at respective independent connection points.

The second supply line 72A is provided with a pressure sensor 141A, a third flow rate regulator 150A, a pressure sensor 142A, and an opening/closing valve 115A in the named order from the upstream side (the branch point 77A side) between the branch points 77A and 62A. The second supply line 72B is provided with a pressure sensor 141B, a third flow rate regulator 150B, a pressure sensor 142B, and an opening/closing valve 115B in the named order from the upstream side (the branch point 77B side) between the branch points 77B and 62B. The second supply line 72C is provided with a pressure sensor 141C, a third flow rate regulator 150C, a pressure sensor 142C, and an opening/closing valve 115C in the named order from the upstream side (the branch point 77B side) between the branch points 77B and 62C.

The pressure sensor 141A measures a pressure of the processing fluid flowing through the second supply line 72A on the upstream side of the third flow rate regulator 150A. Output (measurement result) of the pressure sensor 141A is sent to the control device 6. The pressure sensors 141B and 141C have the same configuration as the pressure sensor 141A.

The third flow rate regulator 150A regulates a flow rate of the processing fluid flowing through the first branch line 73A. The third flow rate regulators 150B and 150C have the same configuration as the third flow rate regulator 150A.

The pressure sensor 142A measures a pressure of the processing fluid flowing through the second supply line 72A between the third flow rate regulator 150A and the opening/closing valve 115A. Output (measurement result) of the pressure sensor 142A is sent to the control device 6. The pressure sensors 142B and 142C have the same configuration as the pressure sensor 142A.

The opening/closing valve 115A allows the processing fluid to flow to the second supply line 72A of the downstream side in an open state and does not allow the processing fluid to flow to the second supply line 72A of the downstream side in a closed state by adjusting on and off of the flow of the processing fluid. The opening/closing valves 115B and 115C have the same configuration as the opening/closing valve 115A.

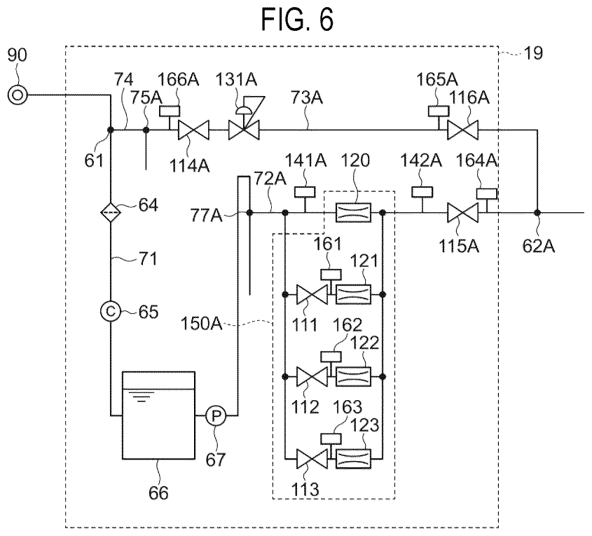

FIG. 6 is a diagram illustrating an example of a configuration of the third flow rate regulator 150A and surrounding elements thereof. The third flow rate regulators 150B and 150C (see FIG. 5) have the same configuration as the third flow rate regulator 150A.

The third flow rate regulator 150A illustrated in FIG. 6 includes opening/closing valves 111 to 113 and orifices 120 to 123. Orifices 121, 122, and 123 are connected in parallel to the orifice 120 and are provided on a downstream side of the opening/closing valves 111 to 113, respectively. The opening/closing valve 111 is connected serially to the orifice 121, the opening/closing valve 112 is connected serially to the orifice 122, and the opening/closing valve 113 is connected serially to the orifice 123.

The orifices 120 to 123 serve to regulate the pressure of the processing fluid by reducing the flow rate of the processing fluid flowing through the second supply line 72A. In particular, the orifices 120 to 123 may circulate the processing fluid with the regulated pressure through the second supply line 72A of the downstream side.

The opening/closing valves 111 to 113 allow the processing fluid to flow to the second supply line 72A of the downstream side in an open state and do not allow the processing fluid to flow to the second supply line 72A of the downstream side by adjusting on and off of the flow of the processing fluid.

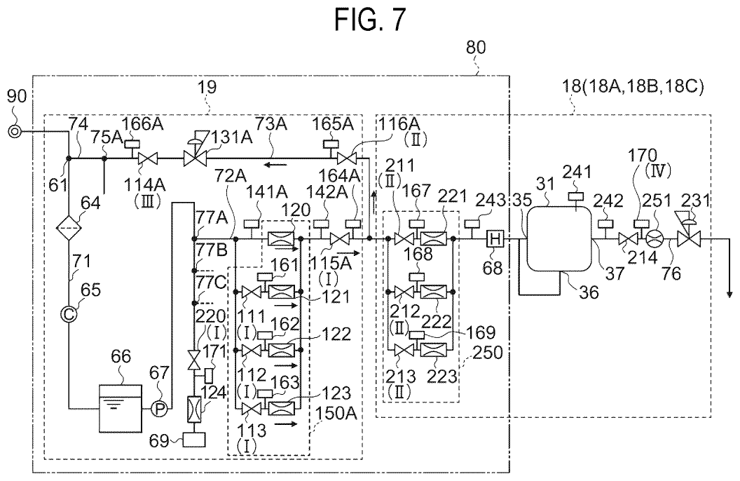

FIG. 7 is a diagram illustrating an example of a configuration of a substrate drying process system (including a fluid supply system) including the drying unit 18 (see FIG. 4) and the supply unit 19 (see FIG. 6).

In general, even if an opening/closing valve is in a closed state, fluid leakage may occur in the opening/closing valve, which may cause a fluid to leak from an upstream flow path to a downstream flow path. It is not easy to specify the opening/closing valve in which such leakage occurs. In particular, in a case in which a large number of opening/closing valves is provided, it may take a lot of labor to find a specific opening/closing valve in which such leakage occurs. For this reason, in practice, in a case in which the leakage occurs in any of opening/closing valves, all opening/closing valves in which such leakage may possibly occur are replaced with new ones.

In the present embodiment, a plurality of temperature measurers 161 to 171 is provided so as to correspond to a plurality of opening/closing valves, respectively. Further, the control device 6 (see FIG. 1) functioning as a leakage determiner determines whether or not leakage of the processing fluid occurs in the plurality of opening/closing valves based on measurement results (that is, changes in measured temperatures) of the plurality of temperature measurers 161 to 171.

The control device 6 may perform any control process based on the result of the leakage determination. For example, when an opening/closing valve determined to have leaked the processing fluid is present, the control device 6 may issue an alarm with respect to an operator, or may control various devices such that the substrate processing apparatus 1 stops processing. By such an alarm, the operator may recognize a specific opening/closing valve in which the leakage of the processing fluid has occurred. This prompts the operator to repair or replace the specific opening/closing valve with a new one. When the alarm is issued, a part or all of processing performed in the substrate processing apparatus 1 does not necessarily have to be stopped. A method and content of the alarm are not particularly limited. The control device 6 may control an alarm device (not illustrated) to send a message prompting to repair or replace the opening/closing valve, which is determined to have the leakage of the processing fluid, with a new one, to the operator using a display and/or voice. After the alarm is issued, a confirmation message asking the operator whether the repair or replacement of the opening/closing valve, which is determined to have the leakage of the processing fluid, with a new one, has been completed, may be generated using the alarm device or other devices.

In the example illustrated in FIG. 7, while temperature measurers are uniquely to all the opening/closing valves provided in the pipe of the drying unit 18 and the supply unit 19, they may be uniquely to only some of the opening/closing valves. Specifically, in FIGS. 4 to 7, the temperature measurers are respectively assigned to the opening/closing valves indicated by reference numerals 111 to 113, 114A to 114C, 115A to 115C, 116A to 116C, and 211 to 214. More specifically, the temperature measurers 161 to 163 are provided for the opening/closing valves 111 to 113, and the temperature measurers 167 to 170 are provided for the opening/closing valves 211 to 214. Temperature measurers 166A to 166C are provided for the opening/closing valves 114A to 114C illustrated in FIG. 5, temperature measurers 164A to 164C are provided for the opening/closing valves 115A to 115C, and temperature measurers 165A to 165C are provided for the opening/closing valves 116A to 116C.

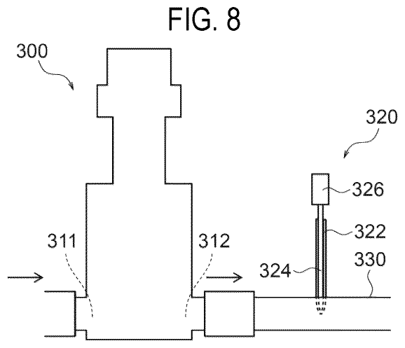

FIG. 8 is a schematic diagram illustrating an example of a configuration of an opening/closing valve 300 (in an appearance thereof) and a temperature measurer 320 (in a cross section thereof). The opening/closing valve 300 illustrated in FIG. 8 is applicable to one or more (for example, all) of the plurality of opening/closing valves illustrated in FIGS. 4 to 7. Similarly, the temperature measurer 320 illustrated in FIG. 8 is applicable to one or more (for example, all) of the plurality of temperature measurers illustrated in FIGS. 4 to 7.

The opening/closing valve 300 may be configured as any type of valve, such as an air-operated valve, and includes an inflow passage 311 connected to a pipe on the upstream side, an outflow passage 312 connected to a pipe 330 on the downstream side, and a valve body (not illustrated) that causes the inflow passage to be in communication with or to be blocked from the outflow passage. The temperature measurer 320 measures a temperature of at least one of a member located on a downstream side of the opening/closing valve 300 or an inner side of the member and transmits its measurement result to the control device 6 (the leakage determiner; see FIG. 1). Herein, the “member located on a downstream side of the opening/closing valve 300” may be, for example, a portion of the pipe 330 connected to the outflow passage or a member connected to the outflow passage via the pipe 330 but is not limited thereto.

In the examples illustrated in FIGS. 4 to 7, each temperature measurer is provided in a portion of a pipe located on a downstream side of a corresponding opening/closing valve and measures the temperature of the portion (for example, a surface) of the pipe in an installation place and/or an inner side (for example, the processing fluid) of the portion of the pipe in the installation place.

The temperature measurer 320 in the example illustrated in FIG. 8 is installed in the pipe (downstream-side pipe) 330 located on a downstream side of the corresponding opening/closing valve 300 and measures the temperature of the processing fluid flowing through an inner side of the downstream-side pipe 330. The temperature measurer 320 includes a temperature sensor 324, a measurement body 326 connected to the temperature sensor 324, and a sheath tube 322 that covers one end of the temperature sensor 324. One end of the temperature sensor 324 is disposed at an inner flow path of the downstream-side pipe 330 while being covered by the sheath tube 322 and functions as a sensor part which measures the temperature of the processing fluid flowing through the flow path of the downstream-side pipe 330. The sheath tube 322 is a sensor cover and has water resistance and strength capable of effectively preventing the processing fluid in the downstream-side pipe 330 from coming into contact with the temperature sensor 324 and thermal conductivity capable of effectively transferring the temperature of the processing fluid to the temperature sensor 324.

According to the temperature measurer 320 illustrated in FIG. 8, since the sensor part of the temperature sensor 324 may be positioned close to the center of a cross section of the downstream-side pipe 330 (particularly the inner flow path), it is advantageous in accurately measuring the temperature of the processing fluid flowing through the downstream-side pipe 330. The temperature measured by the temperature sensor 324 (that is, the measured temperature of the processing fluid inside the downstream-side pipe 330) is transmitted from the measurement body 326 to the control device 6 (the leakage determiner).

The control device 6 (see FIG. 1) of the present embodiment determines whether or not the leakage of the processing fluid occurs in the plurality of opening/closing valves installed in the pipe. That is, the temperature of the processing fluid is measured by a corresponding temperature measurer in a state in which the upstream-side pipe connected to the inflow passage of the opening/closing valve is filled with a pressurized processing fluid and thus an internal pressure of the upstream-side pipe is higher than that of the downstream-side pipe connected to the outflow passage as the opening/closing valve is closed. Specifically, the temperature is measured by the corresponding temperature measurer in a state in which the inflow passage is filled with the pressurized processing fluid and thus the internal pressure of the inflow passage is higher than that of the outflow passage as the opening/closing valve is closed to cause the inflow passage is blocked from the outflow passage by the valve body. Based on a result (measured temperature) of the temperature measurement performed in this way, the control device 6 determines whether or not the leakage of the processing fluid occurs in each opening/closing valve.

When the leakage of the processing fluid occurs in the opening/closing valve, the process fluid leaks from the inflow passage to the outflow passage even if the opening/closing valve is closed. When the leakage occurs in a state in which the internal pressure of the inflow passage is higher than the internal pressure of the outflow passage as described above, the processing fluid leaking into the outflow passage expands adiabatically. As a result, the temperatures of the member located on the downstream side of the opening/closing valve and the inner side of the member are lowered.

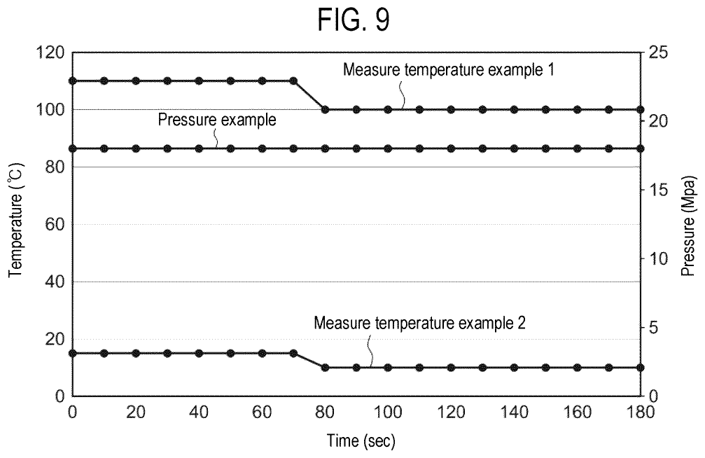

FIG. 9 is a graph (simulation graph) illustrating an example of the internal pressure of the inflow passage of the opening/closing valve and an example of the temperature measured by the corresponding temperature measurer, in which the horizontal axis indicates time (seconds), the vertical axis on the left indicates temperature (degrees C.), and the vertical axis on the right indicates pressure (MPa).

FIG. 9 illustrates a measurement example (“Measurement Temperature Example 1”) of the temperature measurer 170 corresponding to the opening/closing valve 214 on the downstream side of the heater 68, and a measurement example (“Measurement Temperature Example 2”) of the temperature measurer 170 corresponding to the opening/closing valve (for example, the opening/closing valve 115A) on the upstream side of the heater 68. Further, “Pressure Example” illustrated in FIG. 9 is common to “Measurement Temperature Example 1” and “Measurement Temperature Example 2” and illustrates the internal pressure of the inflow passage of the opening/closing valve corresponding to the temperature measurer 170 that has acquired “Measurement Temperature Example 1” and “Measurement Temperature Example 2”.

An object measured in Measurement Temperature Example 1 illustrated in FIG. 9 (the portion of the pipe or the inner side of the portion of the pipe in the examples illustrated in FIGS. 4 to 7) has an inherently high temperature, whereas an object measured in Measurement Temperature Example 2 (the portion of the pipe or the inner side of the portion of the pipe in the examples illustrated in FIGS. 4 to 7) has an inherently low temperature. For each of Measurement Temperature Example 1 and Measurement Temperature Example 2 illustrated in FIG. 9, the leakage of the processing fluid has occurred in the corresponding opening/closing valve during the temperature measurement. In particular, a timing of leakage occurrence was set to a timing at which the same time (about 70 seconds in the example illustrated in FIG. 9) had elapsed from the start of measurement (0 seconds) in Measurement Temperature Example 1 and Measurement Temperature Example 2.

As is apparent from FIG. 9, regardless of the inherent temperature as an object to be measured, the temperature measured by the corresponding temperature measurer decreases due to the leakage of the processing fluid from an opening/closing valve.

The control device 6 determines whether or not a temperature drop caused by the adiabatic expansion occurs based on the measurement result of the temperature measurer. When it is determined that the temperature drop caused by the adiabatic expansion has occurred, the control device 6 recognizes that the leakage of the processing fluid has occurred in the corresponding opening/closing valve. Whether or not the temperature drop caused by the adiabatic expansion has occurred may be determined by any method, and typically may be determined by comparing the temperature measured by the temperature measurer with a predetermined determination threshold temperature. That is, when the temperature measured by the temperature measurer is lower than the determination threshold temperature, it may be determined that the leakage of the processing fluid has occurred in the corresponding opening/closing valve. When the measured temperature is equal to or higher than the determination threshold temperature, it may be determined that no leakage has occurred in the corresponding opening/closing valve.

For each opening/closing valve, the control device 6 may determine that no leakage of the processing fluid has occurred when the temperature measured by the corresponding temperature measurer is within a determination temperature range, and may determine that the leakage of the processing fluid has occurred when the temperature measured by the corresponding temperature measurer falls outside the determination temperature range. The control device 6 may determine whether or not the leakage of the processing fluid occurs in the corresponding opening/closing valve based on a plurality of measured temperatures acquired multiple times by the temperature measurer. For example, when all of the plurality of measured temperatures acquired by the temperature measurer performing periodic measurement over a certain period of time are lower than the determination threshold temperature or fall outside the determination temperature range, the control device 6 may determine that the leakage of the processing fluid has occurred in the corresponding opening/closing valve. On the other hand, when one or more of the plurality of measured temperatures are equal to or higher than the determination threshold temperature or fall within the determination temperature range, the control device 6 may determine that no leakage of the processing fluid has occurred in the corresponding opening/closing valve. Herein, the “certain period of time” is not particularly limited but may be set appropriately based on accuracy of the temperature measurement by the temperature measurer and other factors.

A normal temperature of an object measured by the temperature measurer during a normal operation (normal processing) varies between objects. For example, normal temperatures during normal operations at a place heated by heat emitted from the heater 68, a heated processing fluid, and a place through which the heated processing fluid flows are relatively high. On the other hand, normal temperatures during normal operations at a place not heated by heat emitted from the heater 68, a processing fluid below an environmental temperature (for example, room temperature (5 to 35 degrees C.)), and a place through which the processing fluid below the environmental temperature flows are relatively low. Therefore, the above-mentioned determination threshold temperature and determination temperature range are determined for each object based on the normal temperature during the normal operation of the object.

Next, a basic operation example of the drying unit 18 and the supply unit 19 in a substrate processing method (substrate drying process method) will be described.

A gaseous processing fluid supplied from the processing fluid source 90 to the first supply line 71 is supplied to the capacitor 65 via the filter 64, and is cooled and liquefied by the capacitor 65. The liquefied processing fluid is stored in the tank 66. Such a liquid processing fluid stored in the tank 66 becomes a high-pressure fluid by the pump 67, and a portion thereof is supplied to the drying units 18A to 18C. The other portion of the high-pressure fluid flows through the first branch lines 73A to 73C and the second branch line 74 and then returns to the first supply line 71 for circulation.

The high-pressure fluid supplied to the drying units 18A to 18C is heated to a supercritical state by the heater 68. Such a high-pressure supercritical processing fluid is supplied to the processing chamber inside the main body 31 and is use to process (dry-process) the substrate W in the processing chamber. The processing fluid used to process the substrate W and discharged from the processing chamber is received by the discharge line 76 (fluid discharger) connected to the processing chamber of the main body 31 and is sent to a subsequent stage via the discharge line 76.

Next, an example of a method of detecting the presence or absence of the occurrence the leakage of the processing fluid in the opening/closing valve will be described.

A timing at which a leakage occurrence detection flow (leakage occurrence detection method) described below is implemented is not particularly limited but may be performed before, after, and/or during the above-mentioned substrate processing flow (substrate drying process method). Therefore, the leakage occurrence detection flow may be performed in a failure detection sequence performed separately from a normal substrate processing sequence or in the normal substrate processing sequence, and the presence or absence of the leakage occurrence of the processing fluid in each opening/closing valve may be constantly monitored.

As described above, in order to determine the presence or absence of the leakage occurrence of the processing fluid in the opening/closing valve, a process (pressurization process) in which the inflow passage is filled with the pressurized processing fluid while the opening/closing valve is closed, and a process (temperature measurement process) in which the temperature is measured by the corresponding temperature measurer are performed. In the present embodiment, the pressurization process and the temperature measurement process are performed sequentially from the opening/closing valve of the upstream side toward the downstream side.

That is, in the example illustrated in FIG. 7, first, it is determined whether or not the leakage of the processing fluid is detected in the opening/closing valves 111 to 113, 115A to 115C, and 220 located at the most upstream side, which are marked with the symbol “I”. Specifically, in a state in which the opening/closing valves 111 to 113, 115A to 115C, and 220 of objects are closed, the processing fluid is sent to the opening/closing valves as objects by the pump 67 and opening/closing valves located on a downstream side of the opening/closing valves as objects are open. As a result, as the inflow passages of the opening/closing valves 111 to 113, 115A to 115C, and 220 as objects are filled with the high-pressure processing fluid, the outflow passages are regulated to have a lower pressure (for example, atmospheric pressure) than the internal pressure of the inflow passages. In this manner, the corresponding temperature measurers 161 to 163, 164A to 164C, and 171 measure temperatures in a state in which there is a relatively large pressure difference between the inflow passages and the outflow passages, and the measurement result is sent to the control device 6. Based on the measured temperatures sent from the temperature measurers 161 to 163, 164A to 164C, and 171 in this manner, the control device 6 detects and determines whether or not the leakage of the processing fluid have occurred in the opening/closing valves 111 to 113, 115A to 115C, and 220 located at the farthest upstream side.

Thereafter, it is determined whether or not the leakage of the processing fluid is detected in the opening/closing valves 116A to 116C and 211 to 213 located at the next upstream side, which are marked with the symbol “II” in FIG. 7. Specifically, as the opening/closing valves 116A to 116C and 211 to 213 as objects are closed, opening/closing valves (except for the opening/closing valve 220) located on upstream and downstream sides of the opening/closing valves as objects are open, and the processing fluid is sent to the opening/closing valves as objects by the pump 67. As a result, the inflow passages of the opening/closing valves 116A to 116C and 211 to 213 as objects are filled with the high-pressure processing fluid, and the outflow passages are regulated to have a lower pressure (for example, atmospheric pressure) than the internal pressure of the inflow passages. In this manner, in a state in which there is a relatively large pressure difference between the inflow passages and the outflow passages, the temperature measurement is performed by the corresponding temperature measurers 165A to 165C and 167 to 169, and the measurement result is sent to the control device 6. In this way, the control device 6 detects and determines whether or not the leakage of the processing fluid has occurred in the opening/closing valves 116A to 116C and 211 to 213 based on the measured temperatures sent by the temperature measurers 165A to 165C and 167 to 169.

Thereafter, it is determined whether or not the leakage of the processing fluid is detected in the opening/closing valves 114A to 114C located at the next upstream side, which are marked with the symbol “III” in FIG. 7. Specifically, as the opening/closing valves 114A to 114C as objects are closed, the opening/closing valves 111 to 113, 115A to 115C, and 116A to 116C (except for the opening/closing valve 220) located on the upstream side of the opening/closing valves as objects are open. In addition, the opening/closing valves 211 to 214 are closed. The processing fluid is sent to the opening/closing valves as objects by the pump 67. As a result, the inflow passages of the opening/closing valves 114A to 114C as objects are filled with the high-pressure processing fluid, and the outflow passages are regulated to have a lower pressure (for example, atmospheric pressure) than those of the inflow passages. In this manner, in a state in which there is a relatively large pressure difference between the inflow passages and the outflow passages, the temperature measurement is performed by the corresponding temperature measurers 166A to 166C, and the measurement result is sent to the control device 6. In this way, the control device 6 detects and determines whether or not the leakage of the processing fluid has occurred in the opening/closing valves 114A to 114C based on the measured temperatures sent by the temperature measurers 166A to 166C.

Thereafter, it is determined whether or not the leakage of the processing fluid is detected in the opening/closing valve 214 located at the next upstream side, which is marked with the symbol “IV” in FIG. 7. Specifically, as the opening/closing valve 214 as an object is closed, opening/closing valves 111 to 113, 115A to 115C, and 211 to 213 (except for the opening/closing valve 220) located on the upstream side of the opening/closing valve as an object are open. In addition, the opening/closing valves 114A to 114C and 116A to 116C may be in any one of an open state and a closed state as long as the opening/closing valves may fill the processing fluid in a desired high-pressure state into the inflow passage of the opening/closing valve 214 as an object. The processing fluid is sent to the opening/closing valve 214 as an object by the pump 67. As a result, the inflow passage of the opening/closing valve 214 as an object is filled with the high-pressure processing fluid, and the outflow passage is regulated to have a lower pressure (for example, atmospheric pressure) than that of the inflow passage. In this manner, in a state in which there is a relatively large pressure difference between the inflow passage and the outflow passage, the temperature measurement is performed by the corresponding temperature measurers 170, and the measurement result is sent to the control device 6. In this way, the control device 6 detects and determines whether or not the leakage of the processing fluid has occurred in the opening/closing valve 214 based on the measured temperature sent by the temperature measurer 170.

By performing a series of leakage occurrence detection flows described above, it is possible to detect and determine whether or not the leakage of the processing fluid has occurred in each of all the opening/closing valves included in the drying unit 18 and the supply unit 19.

In the above-mentioned leakage occurrence detection flow, the form of the fluid in the inflow passage and the outflow passage of the opening/closing valve to be detected and determined is not particularly limited but may be in any of a gaseous state, a liquid state, and/or a supercritical state.

Therefore, at least one of the plurality of temperature measurers may measure the temperature in a state in which a gaseous processing fluid is present in at least one of the outflow passage of the corresponding opening/closing valve or the portion of the pipe on the downstream side of the valve body of the corresponding opening/closing valve.

Further, at least one of the plurality of temperature measurers may measure the temperature in a state in which a fluid in a liquid state or a supercritical state is present in the inflow passage of the corresponding opening/closing valve. Even in the above-mentioned leakage occurrence detection flow, the heater 68 heats the processing fluid in a gaseous state or a liquid state flowing through the second supply line 72 to generate the supercritical processing fluid and sends the supercritical fluid to the downstream side. Therefore, in a state in which there is the fluid in a liquid state or a supercritical state in the inflow passage of the opening/closing valve 214 located on the downstream side of the heater 68 and the main body 31, the temperature of the fluid is measured by the corresponding temperature measurer 170.

When detecting and determining whether or not the leakage of the processing fluid has occurred in the opening/closing valve 214, the above-mentioned pressurization process and temperature measurement process may be performed in a state in which there is no substrate W inside the processing chamber in the main body 31.

As described above, according to the present embodiment, the presence or absence of the leakage of the processing fluid in each opening/closing valve may be easily and quickly detected and determined based on the measured temperature. As a result, the fluid supply system, the substrate processing apparatus, and the fluid supply method of the present embodiment are useful for early detection of abnormality in the opening/closing valve, reduction in the number of processes and in labor needed to detect and determine the presence or absence of the leakage of the processing fluid in each opening/closing valve, and prevention of secondary damage such as product damage due to emergency stop of the apparatus.

### [Modifications]

In the above-described embodiment, while each temperature measurer measures the temperature of the portion (for example, surface) of the pipe on the downstream side of the corresponding opening/closing valve or the inner side of the portion of the pipe, the temperature measurer may measure the temperature of any member provided on the downstream side of the opening/closing valve.

The installation positions and number of opening/closing valves provided in the pipe are not limited to those in the above examples (see FIGS. 4 to 7), and any number of opening/closing valves may be installed at any places in the pipe. For example, an opening/closing valve may be provided between the heater 68 and the main body 31 illustrated in FIG. 7, and the temperature measurer may be provided to measure a temperature of at least one of a member located on the downstream side of the opening/closing valve and an inner side of the member.

According to the present disclosure in some embodiments, it is advantageous to detect leakage of a fluid in each of a plurality of opening/closing valves.

It should be noted that the embodiments and modifications disclosed herein are merely examples in all respects and are not to be construed in a limited way. The above-described embodiments and modifications may be omitted, substituted, and modified in various ways without departing from the scope and spirit of the appended claims. For example, the above-described embodiments and modifications may be partially or wholly combined with each other, and embodiments other than those described above may be combined with the above-described embodiments or modifications. Additionally, the advantages of the present disclosure described herein are merely examples, and other advantages may be obtained.

Further, the technical categories that embody the above-described technical ideas are not particularly limited. For example, the above-described technical ideas may be implemented by computer programs for causing a computer to execute one or more procedures (steps) included in a method for manufacturing or using the above apparatus. Further, the above-described technical ideas may be embodied by a non-transitory computer-readable recording medium storing such a computer program.

What is claimed is:

1. A fluid supply system, comprising:
a pipe;
a fluid supplier configured to supply a fluid to the pipe so as to cause the fluid to flow from an upstream side to a downstream side in the pipe;
a plurality of opening/closing valves provided in the pipe, each of the plurality of opening/closing valves having an inflow passage, an outflow passage, and a valve body configured to cause the inflow passage to be in communication with or be blocked from the outflow passage;
a plurality of temperature measurers provided to correspond respectively to the plurality of opening/closing valves, each of the plurality of temperature measurers being configured to measure a temperature of at least one of a member located on a downstream side of a corresponding opening/closing valve among the plurality of opening/closing valves or an inner side of the member; and
a leakage determiner configured to determine whether or not leakage of the fluid occurs in the plurality of opening/closing valves,
wherein the leakage determiner determines whether or not the leakage of the fluid occurs in each of the plurality of opening/closing valves based on a temperature measured by a corresponding temperature measurer among the plurality of temperature measurers, in a state in which the inflow passage is filled with a pressurized fluid so that an internal pressure of the inflow passage becomes higher than an internal pressure of the outflow passage as the corresponding opening/closing valve is closed to cause the inflow passage is blocked from the outflow passage by the valve body.

2. The fluid supply system of claim 1, wherein at least one of the plurality of temperature measurers measures a temperature in a state in which the fluid in a gaseous state is present in at least one of the outflow passage of the corresponding opening/closing valve or a portion of the pipe on a downstream side of the valve body of the corresponding opening/closing valve.

3. The fluid supply system of claim 1, wherein at least one of the plurality of temperature measurers measures a temperature in a state in which the fluid in a liquid state or a supercritical state is present in the inflow passage of the corresponding opening/closing valve.

4. The fluid supply system of claim 1, wherein at least one of the plurality of temperature measurers measures a temperature of an inner side of a portion of the pipe at the downstream side of the corresponding opening/closing valve.

5. The fluid supply system of claim 1, wherein at least one of the plurality of temperature measurers measures a surface temperature of a portion of the pipe at the downstream side of a corresponding opening/closing valve.

6. The fluid supply system of claim 1, wherein the outflow passage of at least one of the plurality of opening/closing valves is connected to an exhauster via the pipe provided with an orifice configured to locally narrow a flow path through which the fluid flows.

7. The fluid supply system of claim 1, wherein the leakage determiner determines that no leakage of the fluid has occurred when the temperature measured by the corresponding temperature measurer for each of the plurality of opening/closing valves is within a determination temperature range over a certain period of time.

8. The fluid supply system of claim 1, wherein an operation of filling the inflow passage with the pressurized fluid as the opening/closing valve is closed and an operation of measuring the temperature by the corresponding temperature measurer to determine whether or not the leakage of the fluid occurs in each of the plurality of opening/closing valves, are sequentially performed starting from the opening/closing valve on the upstream side.

9. The fluid supply system of claim 1, wherein the fluid includes carbon dioxide.

10. A substrate processing apparatus, comprising:
a processing chamber to which a fluid in a supercritical state is supplied and in which a substrate is processed using the fluid;
a supply pipe connected to the processing chamber and configured to supply the fluid to the processing chamber;
a discharge pipe connected to the processing chamber and configured to receive the fluid discharged from the processing chamber;
a plurality of opening/closing valves including at least one opening/closing valve provided in the supply pipe and at least one opening/closing valve provided in the discharge pipe;
a plurality of temperature measurers provided to correspond respectively to the plurality of opening/closing valves; and
a leakage determiner configured to determine whether or not leakage of the fluid occurs in each of the plurality of opening/closing valves,
wherein each of the plurality of opening/closing valves includes an inflow passage, an outflow passage, and a valve body configured to cause the inflow passage to be in communication with or be blocked from the outflow passage,
wherein each of the plurality of temperature measurers measures a temperature of at least one of a member located on a downstream side of a corresponding opening/closing valve among the plurality of opening/closing valves or an inner side of the member, and
wherein the leakage determiner determines whether or not the leakage of the fluid occurs in each of the plurality of opening/closing valves based on a temperature measured by a corresponding temperature measurer among the plurality of temperature measurers, in a state in which the inflow passage is filled with a pressurized fluid so that an internal pressure of the inflow passage becomes higher than an internal pressure of the outflow passage as the corresponding opening/closing valve is closed to cause the inflow passage is blocked from the outflow passage by the valve body.

11. The substrate processing apparatus of claim 10, wherein an operation of filling the inflow passage with the pressurized fluid as the opening/closing valve is closed and an operation of measuring the temperature by the corresponding temperature measurer to determine whether or not the leakage of the fluid occurs in the at least one opening/closing valve provided in the discharge pipe, are performed in a state in which there is no substrate inside the processing chamber.

12. A fluid supply method, comprising:
supplying a fluid to a pipe so as to cause the fluid to flow from an upstream side to a downstream side in the pipe;
causing, by a valve body, an inflow passage to be in communication with or be blocked from an outflow passage, the inflow passage and the outflow passage being included in each of a plurality of opening/closing valves provided in the pipe;
measuring, by each of a plurality of temperature measurers provided to correspond respectively to the plurality of opening/closing valves, a temperature of at least one of a member located on a downstream side of a corresponding opening/closing valve among the plurality of opening/closing valves or an inner side of the member; and
determining whether or not leakage of the fluid occurs in the plurality of the opening/closing valves based on temperatures measured by the plurality of temperature measurers,
wherein the determining whether or not the leakage of the fluid occurs is performed for each of the plurality of opening/closing valves based on a temperature measured by a corresponding temperature measurer among the plurality of temperature measurers, in a state in which the inflow passage is filled with a pressurized fluid so that an internal pressure of the inflow passage becomes higher than an internal pressure of the outflow passage as the corresponding opening/closing valve is closed to cause the inflow passage is blocked from the outflow passage by the valve body.
